(19) United States
(12) Patent Application Publication
(10) Pub. No.: US 2025/0284054 A1
(43) Pub. Date: Sep. 11, 2025

(54) BURIED OPTICAL WAVEGUIDE STRUCTURE, INTEGRATED SEMICONDUCTOR LASER DEVICE, AND BURIED OPTICAL WAVEGUIDE STRUCTURE MANUFACTURING METHOD

(71) Applicant: FURUKAWA ELECTRIC CO., LTD., Tokyo (JP)

(72) Inventors: Teruyuki NAKAMURA, Chiba (JP); Masaki WAKABA, Tokyo (JP); Naoya HOJO, Chiba (JP); Tatsuya KIMOTO, Tokyo (JP)

(73) Assignee: FURUKAWA ELECTRIC CO., LTD., Tokyo (JP)

(21) Appl. No.: 19/218,791

(22) Filed: May 27, 2025

Related U.S. Application Data
(63) Continuation of application No. PCT/JP2024/000070, filed on Jan. 5, 2024.

(30) Foreign Application Priority Data
Jan. 30, 2023 (JP) 2023-011529

(51) Int. Cl. G02B 6/122; G02B 6/136; H01S 5/026

(52) U.S. Cl. CPC G02B 6/122; G02B 6/136; H01S 5/026

(57) ABSTRACT

A buried optical waveguide structure includes: a waveguide including a first cladding layer, a core layer, and a second cladding layer that are layered in a first direction; and a burying layer that is adjacent to the waveguide in a direction intersecting with the first layer. The waveguide includes a first portion that has a first width in a second direction and that extends in a third direction, a second portion that is shifted from the first portion in the third direction, that is optically connected to the first portion, and that has a second width which is smaller than the first width in the second direction, and a third portion that is adjacent to the first portion in the third direction, and that is optically connected to the first portion.

### CROSS-REFERENCE TO RELATED APPLICATIONS

This application is a continuation of International Application No. PCT/JP2024/000070, filed on Jan. 5, 2024 which claims the benefit of priority of the prior Japanese Patent Application No. 2023-011529, filed on Jan. 30, 2023, the entire contents of which are incorporated herein by reference.

### BACKGROUND OF THE INVENTION

### 1. Field of the Invention

The present disclosure relates to a buried optical waveguide structure, an integrated semiconductor laser device, and a buried optical waveguide structure manufacturing method.

### 2. Description of the Related Art

As a buried optical waveguide structure, a structure is known in which a single wide waveguide is optically connected to a single narrow waveguide (for example, Japanese Patent No. 5100881).

### SUMMARY OF THE INVENTION

As a result of performing diligent research, the inventors found out that, in a buried optical waveguide structure of the abovementioned type, in the vicinity of that end surface of the single wide waveguide which is on the side of the narrow waveguide, sometimes a void is generated and the optical properties undergo a decline due to the reflection of light attributed to the void.

In that regard, it is desirable to provide a buried optical waveguide structure, an integrated semiconductor laser device, and a buried optical waveguide structure manufacturing method in a new and improved manner for enabling holding down a decline in the optical properties associated with the generation of a void.

### SUMMARY OF THE INVENTION

In some embodiments, a buried optical waveguide structure includes: a waveguide including a first cladding layer, a core layer, and a second cladding layer that are layered in a first direction; and a burying layer that is adjacent to the waveguide in a direction intersecting with the first layer, the buried optical waveguide structure being made of semiconductor crystals. The waveguide includes a first portion that has a first width in a second direction intersecting with the first direction and that extends in a third direction intersecting with both of the first direction and the second direction, a second portion that is shifted from the first portion in the third direction, that is optically connected to the first portion, that has a second width which is smaller than the first width in the second direction, and that extends in the third direction, and a third portion that is adjacent to the first portion in the third direction, that is optically connected to the first portion, and that has an end surface in the third direction, the first direction represents a direction of crystal orientation [100], the second direction represents either a direction of crystal orientation [0-11] or a direction of crystal orientation [01-1], the third direction represents either a direction of crystal orientation [011] or a direction of crystal orientation [0-1-1], and a normal direction at each position on the end surface is oriented toward a direction either in between the first direction, the second direction, and the third direction or in between the first direction, an opposite direction of the second direction, and the third direction, and is inclined with respect to either a direction of crystal orientation [111] or a direction of crystal orientation [1-1-1].

In some embodiments, a buried optical waveguide structure includes: a waveguide including a first cladding layer, a core layer, and a second cladding layer that are layered in a first direction; and a burying layer that is adjacent to the waveguide in a direction intersecting with the first layer, the buried optical waveguide structure being made of semiconductor crystals. The waveguide includes a first portion that has a first width in a second direction intersecting with the first direction and that extends in a third direction intersecting with both of the first direction and the second direction, a second portion that is shifted from the first portion in the third direction, that is optically connected to the first portion, and that has a second width which is smaller than the first width in the second direction, and that extends in the third direction, and a third portion that is adjacent to the first portion in the third direction, that is optically connected to the first portion, and that has an end surface in the third direction, the first direction represents direction of crystal orientation [100], the second direction represents direction of crystal orientation [0-11] or direction of crystal orientation [01-1], the third direction represents direction of crystal orientation [011] or direction of crystal orientation [0-1-1], and the end surface includes a portion that has a normal direction oriented toward a direction either in between the first direction, the second direction, and the third direction or in between the first direction, an opposite direction of the second direction, and the third direction, and inclined with respect to either a direction of crystal orientation [111] or a direction of crystal orientation [1-1-1].

In some embodiments, an integrated semiconductor laser device includes: the buried optical waveguide structure; a plurality of waveguides that is optically connected to the first portion on a side that is different from a side on which the first portion is connected to the second portion; and semiconductor lasers that are optically connected to the waveguides on a side that is different from a side on which the waveguides are connected to the first portion.

In some embodiments, a buried optical waveguide structure manufacturing method includes: layering, in a first direction, a first cladding layer, a core layer, and a second cladding layer on a substrate intersecting with the first direction to form a layered body; performing etching on the layered body in an opposite direction of the first direction to form a depressed portion and a waveguide adjacent to the depressed portion; and burying the depressed portion with a burying layer. The waveguide includes a first portion that has a first width in a second direction intersecting with the first direction and that extends in a third direction intersecting with both of the first direction and the second direction, a second portion that is shifted from the first portion in the third direction, that is optically connected to the first portion, that has a second width which is smaller than the first width in the second direction, and that extends in the third direction, and a third portion that is adjacent to the first portion in the third direction, that is optically connected to the first portion, and that has an end surface in the third direction, the first direction represents a direction of crystal orientation [100], the second direction represents either a direction of crystal orientation [0-11] or a direction of crystal orientation [01-1], the third direction represents either a direction of crystal orientation [011] or a direction of crystal orientation [0-1-1], and the end surface includes a portion that has a normal direction oriented toward a direction either in between the first direction, the second direction, and the third direction or in between the first direction, an opposite direction of the second direction, and the third direction, and inclined with respect to either a direction of crystal orientation [111] or a direction of crystal orientation [1-1-1].

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is an illustrative and schematic planar view of a buried optical waveguide structure according to a first embodiment;

FIG. 2 is an II-II cross-sectional view of FIG. 1;

FIG. 3 is an illustrative and schematic cross-sectional view, at an equivalent position to the position illustrated in FIG. 2, illustrating a state in which a layered body is formed by layering a plurality of layers on a substrate during a manufacturing method for manufacturing the buried optical waveguide structure according to the first embodiment;

FIG. 4 is an illustrative and schematic cross-sectional view, at an equivalent position to the position illustrated in FIG. 2, illustrating a state in which etching is performed on the layered body illustrated in FIG. 3 and a waveguide is formed during the manufacturing method for manufacturing the buried optical waveguide structure according to the first embodiment;

FIG. 5 is an illustrative and schematic planar view of a buried optical waveguide structure according to a reference example;

FIG. 6 is a VI-VI cross-sectional view of FIG. 5;

FIG. 7 is a graph that, in the case in which the buried optical waveguide structure according to the reference example transmits the output light of a laser device, illustrates an example of the relationship between the applied current, which is applied to the laser device, and the increase rate of the light output of the laser device with respect to the applied current;

FIG. 8 is a graph that, in the case in which the buried optical waveguide structure according to the first embodiment transmits the output light of a laser device, illustrates an example of the relationship between the applied current, which is applied to the laser device, and the increase rate of the light output of the laser device with respect to the applied current;

FIG. 9 is an illustrative and schematic planar view of a buried optical waveguide structure according to a second embodiment;

FIG. 10 is an illustrative and schematic planar view of a buried optical waveguide structure according to a third embodiment;

FIG. 11 is an illustrative and schematic planar view of a buried optical waveguide structure according to a fourth embodiment;

FIG. 12 is an illustrative and schematic planar view of a buried optical waveguide structure according to a fifth embodiment;

FIG. 13 is an illustrative and schematic planar view of a buried optical waveguide structure according to a sixth embodiment; and

FIG. 14 is an illustrative and schematic planar view of a buried optical waveguide structure according to a seventh embodiment, which is configured as an integrated semiconductor laser device.

### DETAILED DESCRIPTION

Exemplary embodiments of the disclosure are described below. The configurations explained in the embodiments described below as well as the actions and the results (effects) attributed to the configurations are only exemplary. Thus, the disclosure can be implemented also using some different configuration than the configurations disclosed in the embodiments described below. Meanwhile, according to the disclosure, it becomes possible to achieve at least one of various effects (including secondary effects) that are attributed to the configurations.

The embodiments described below include identical constituent elements. Thus, based on the identical configuration according to each embodiment, it becomes possible to achieve identical actions and identical effects. In the following explanation, the identical constituent elements are referred to by the same reference numerals, and their explanation is not given in a repeated manner.

In the present written description, ordinal numbers are assigned only for convenience and with the aim of differentiating among the directions and the portions. Thus, the ordinal numbers neither indicate the priority or the sequencing nor restrict the count.

In the drawings, the X direction is indicated by an arrow X, the Y direction is indicated by an arrow Y, and the Z direction is indicated by an arrow Z. The X direction, the Y direction, and the Z direction intersect with each other and are orthogonal to each other. The X direction can be referred to as the direction of extension. The Y direction can be referred to as the width direction. The Z direction can be referred to as the height direction or the layering direction.

Meanwhile, the drawings are schematic diagrams intended for use in the explanation. Thus, in the drawings, the scale and the ratio does not necessarily match with the actual objects.

### First Embodiment

### Basic Configuration

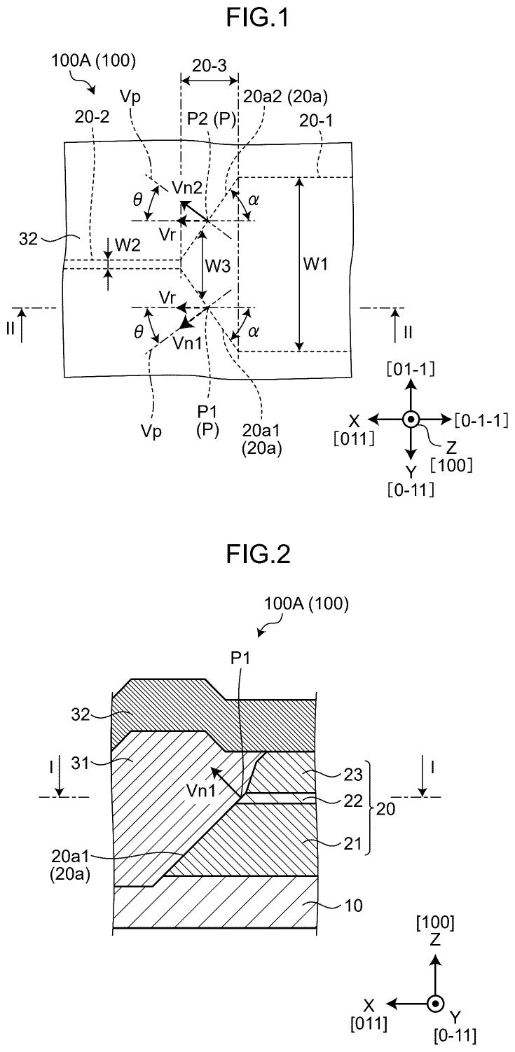

FIG. 1 is a planar view of a buried optical waveguide structure 100A (100) according to a first embodiment.

As illustrated in FIG. 1, the buried optical waveguide structure 100A (100) according to the first embodiment includes three waveguides 20-1 to 20-3 that are arranged in the X direction. The buried optical waveguide structure 100A (100) is made of semiconductor crystals.

The waveguide 20-1 has a substantially constant width W1 in the Y direction, has a substantially constant height in the Z direction, and extends in the X direction. The waveguide 20-1 represents an example of a first portion of a waveguide 20 (see FIG. 2). The width W1 represents an example of a first width.

The waveguide 20-2 has a substantially constant width W2 in the Y direction, has a substantially constant height in the Z direction, and extends in the X direction. As is clear from FIG. 1, the width W2 is smaller than the width W1 of the waveguide 20-1. The waveguide 20-2 is shifted from the waveguide 20-1 in the X direction. The waveguide 20-2 represents an example of a second portion of the waveguide 20. The width W2 represents an example of a second width.

The waveguide 20-3 is positioned in between the waveguides 20-1 and 20-2. In other words, the waveguide 20-3 is adjacent to the waveguide 20-1 in the X direction and is adjacent to the waveguide 20-2 in the opposite direction of the X direction. The waveguides 20-1, 20-3, and 20-2 are arranged in that order in the X direction.

The waveguides 20-1, 20-3, and 20-2 have the same height in the Z direction. A width W3 of the waveguide 20-3 keeps changing as the orientation of the waveguide 20-3 turns more toward the X direction. More particularly, in the first embodiment, at the position of contact between the waveguide 20-3 with the waveguide 20-1, the width W3 is same as the width W1; and, at the position of contact between the waveguide 20-3 with the waveguide 20-2, the width W3 is same as the width W2. As the orientation turns toward the X direction, the width W3 goes on becoming smaller in a linear and gradual manner. The waveguide 20-3 having the abovementioned configuration is optically connected to the waveguide 20-1 as well as the waveguide 20-2. The waveguide 20-3 represents an example of a third portion of the waveguide 20.

In that case, the waveguides 20-1 and 20-3 can represent, for example, multimode interference waveguides that are optically connected to the waveguide 20-2.

FIG. 2 is an II-II cross-sectional view of FIG. 1. As illustrated in FIG. 2, the waveguide 20 includes a first cladding layer 21, a core layer 22, and a second cladding layer 23 that are layered on a substrate 10 in the Z direction. The Z direction represents an example of a first direction.

The first cladding layer 21 is made of, for example, n-InP; and the second cladding layer 23 is made of, for example, p-InP. The core layer 22 is made of, for example, GaInAsP. Moreover, with respect to the waveguide 20, a burying layer 31 is provided adjacent to a direction intersecting with the Z direction. That is, the core layer 22 is enclosed by the first cladding layer 21, the second cladding layer 23, and the burying layer 31. The waveguide 20 and the burying layer 31 are wholly covered by an upper layer 32. The burying layer 31 is made of, for example, p-InP and n-InP; and the upper layer 32 is made of, for example, p-InP. Meanwhile, the burying layer 31 is sometimes covered by an insulation layer (not illustrated). Moreover, depending on the area, a contact layer (not illustrated) or an electrode layer (not illustrated) is also provided on the upper layer 32.

The waveguides 20-1 and 20-3 illustrated in FIG. 1 have the shape illustrated at the I-I position illustrated in FIG. 2, that is, have the shape of side edges (side surfaces 20a) at the central position of the core layer 22 in the Z direction.

### Manufacturing Method

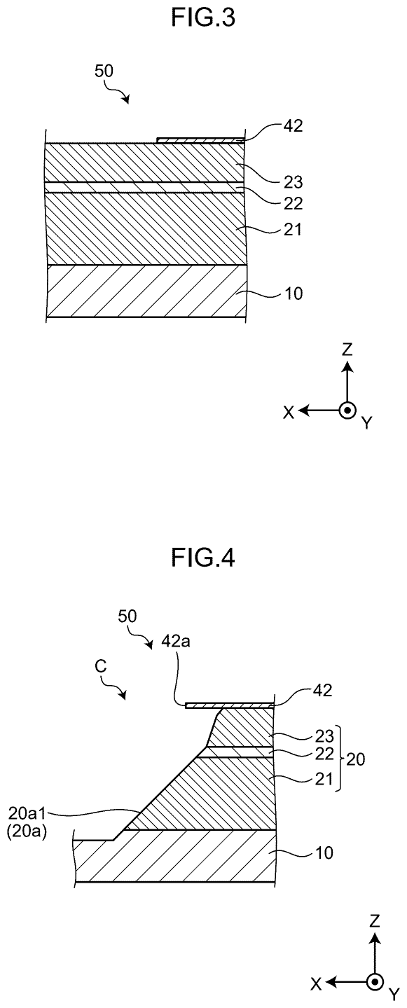

FIGS. 3 and 4 are cross-sectional views, at an equivalent position to the position illustrated in FIG. 2, illustrating the stages in a manufacturing method for manufacturing the buried optical waveguide structure 100A (100).

Firstly, as illustrated in FIG. 3, the first cladding layer 21, the core layer 22, and the second cladding layer 23 are layered on the substrate 10 in the Z direction; and a layered body 50 is formed. Moreover, a dielectric substance mask 42 is formed on the second cladding layer 23. The dielectric substance mask 42 is formed in a predetermined shape. The dielectric substance mask 42 can also be referred to as an etching mask or a mask.

Subsequently, as illustrated in FIG. 4, of the layered body 50, the portion that is exposed from the dielectric substance mask 42 is removed by performing etching in the opposite direction of the Z direction. In this case, the etching implies dry etching or wet etching. As a result of performing this process, a depressed portion C is formed in the layered body 50, and the portion that remains intact without getting removed as the depressed portion C, that is, the portion adjacent to the depressed portion C serves as the waveguide 20.

After attaining the state illustrated in FIG. 4, due to epitaxial growth, the depressed portion C gets buried with the burying layer 31; and, after a sacrifice layer 41 and the dielectric substance mask 42 are removed, the burying layer 31 gets covered by the upper layer 32. Hence, the state illustrated in FIG. 2 is attained.

As illustrated in FIG. 4, the side surfaces 20a of the waveguide 20, which are formed as a result of performing etching of the layered body 50, are inclined with respect to the Z direction. More particularly, the side surfaces 20a are inclined in such a way that, in a virtual plane Vp (see FIG. 1) that is orthogonal to each position of an end edge 42a of the dielectric substance mask 42 in the X direction, the side surfaces 20a approaches to the inside of the dielectric substance mask 42 toward the Z direction. The side surfaces 20a represent examples of an end surface.

### Generation of Voids

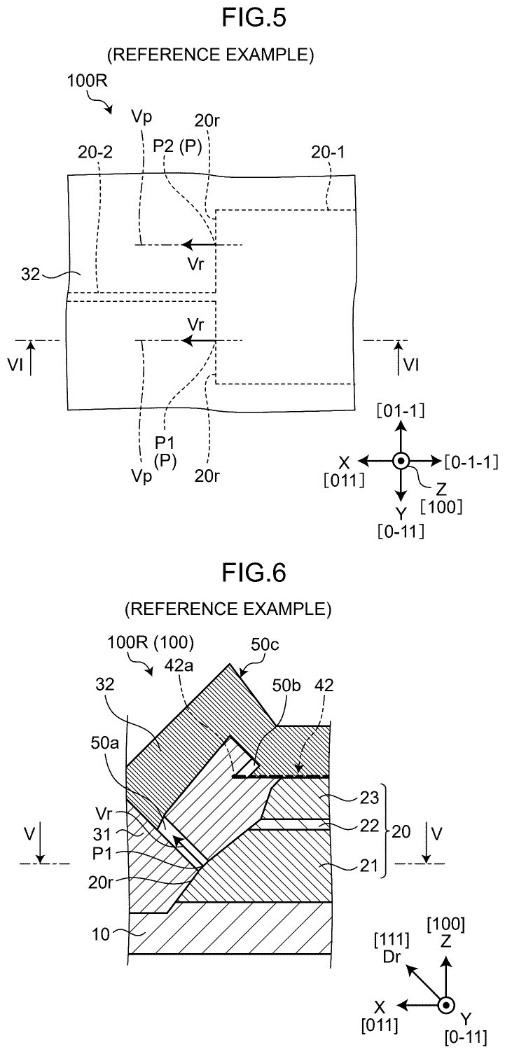

FIG. 5 is a planar view of a buried optical waveguide structure 100R according to a reference example. FIG. 6 is a VI-VI cross-sectional view of FIG. 5. The dashed line illustrated in FIG. 5 indicates the shape of a side surface 20r of the waveguide 20 at a V-V position illustrated in FIG. 6.

As a result of performing diligent research, the inventors found out that, in the buried optical waveguide structure 100R according to the reference example, during the process of forming the burying layer 31 and the upper layer 32, sometimes voids 50a and 50b (see FIG. 6) are generated in the burying layer 31 and the upper layer 32 due to the relationship between the normal direction and the crystal orientation at each position on the side surfaces 20a.

As is clear from FIG. 5, in the reference example, the waveguide 20-3 is absent, and the side surface 20r serving as the end surface of the waveguide 20-1 in the X direction extends substantially along the Y direction.

In the etching process in which the depressed portion C is formed, the side surface 20r extending in the Y direction is formed using the dielectric substance mask 42 that has the end edge 42a extending in the Y direction (see FIG. 6). In that case, in the etching process, in the virtual plane Vp (see FIG. 5, the XZ plane) that is orthogonal to the end edge 42a extending in the Y direction, the side surface 20r is inclined in such a way that the side surface 20r approaches the inside of the dielectric substance mask 42 toward the Z direction. In the buried optical waveguide structure 100R according to the reference example, the X direction, that is, the direction of extension of the waveguide 20 represents the direction of the crystal orientation [011]; the Y direction, that is, the width direction of the waveguide 20 represents the direction of the crystal orientation [0-11]; and the Z direction, that is, the layering direction of the waveguide 20 and the burying layer 31 represents the direction of the crystal orientation [100]. In that case, on the side surface 20r, sometimes a portion P1 appears that has a normal direction Dr toward the exactly intermediate direction between the X direction and the Z direction, that is, toward the direction of the crystal orientation [111]. Meanwhile, assume that a normal vector Vr represents the unit vector oriented toward the normal direction Dr.

For example, when the material constituting the waveguide 20 and the burying layer 31 is made of a III-V compound semiconductor having a zinc blende structure, in the portion P1 having the normal direction Dr oriented toward the direction of the crystal orientation [111], the coupling force among the crystals becomes weak. For that reason, in the epitaxial growth constituting the burying layer 31, it is estimated that the void 50a, that is, the region having no deposition of the burying layer 31 appears in the portion P1 that has the normal direction Dr oriented toward the direction of the crystal orientation [111].

Accompanying the appearance of the portion P1 and the void 50a, in the epitaxial growth, the deposition of the burying layer 31 is accelerated toward the direction orthogonal to the normal direction Dr, that is, in the example illustrated in FIG. 6, toward a direction in between the Z direction and the opposite direction of the X direction (in the plane of FIG. 6, toward the upper right direction; hereinafter, referred to as the growth direction). In that case, in that portion in the growth direction which is behind the dielectric substance mask 42, sometimes the void 50b is generated.

The portion P1 is not limited to be at the position illustrated in FIG. 6, and there is a possibility that the portion P1 appears at another position on the side surface 20r. Hence, when the voids 50a and 50b appear relatively closer to the core layer 22 of the waveguide 20, there occurs reflection and scattering of the guided light, thereby leading to a decline in the transmission characteristics of the light in the waveguide 20. Moreover, also regarding the portion having the normal direction oriented toward the direction of the crystal orientation [1-1-1], the same problem occurs.

### Structure Enabling Holding Down Voids

In the buried optical waveguide structure 100A (100) according to the first embodiment, the waveguide 20-3 is disposed and, the normal direction at each position on the side surfaces 20a of the waveguide 20-3 is set to be inclined with respect to the direction of the crystal orientation [111]. As explained earlier, the direction of the crystal orientation [111] is in the exactly intermediate direction between the X direction and the Z direction. That point is explained below with reference to FIGS. 1 and 2.

The side surfaces 20a include a side surface 20a1 representing the portion extending in the opposite direction of the X direction along the Y direction, and includes a side surface 20a2 representing the portion extending in the X direction along the Y direction.

As illustrated in FIG. 2, in the portion P1 (P) on the side surface 20a1, the normal vector Vn1 is oriented toward a direction in between the X direction and the Z direction and, as illustrated in FIG. 1, is oriented toward a direction in between the X direction and the Y direction. That is, the normal vector Vn1, in other words, the normal direction of the portion P1 is oriented toward a direction in between the X direction, the Y direction, and the Z direction. Regarding the portion P1 (P), the X direction represents an example of a third direction, and the Y direction represents an example of a second direction.

As illustrated in FIG. 1, the side surface 20a1 is configured in such a way that, when viewed from the opposite direction of the Z direction, an angular difference θ occurs between the orthogonal projection of the normal vector Vn1 at each position on the side surface 20a1 onto the virtual plane intersecting with the Z direction (i.e., the XY plane) and the X direction (i.e., the angular difference θ occurs between the arrow indicating Vn1 in FIG. 1 and the X direction). The angular difference θ represents an example of a first angular difference.

As a result of forming the side surface 20a1 (20a) in such a way that the abovementioned state of the normal vector Vn1 is attained, it becomes possible to attain the state in which the normal direction of each portion P1 on the side surface 20a1 (20a), that is, the direction in which the normal vector Vn1 is oriented is inclined with respect to the direction of the crystal orientation [111].

In an identical manner to the portion P1 illustrated in FIG. 2, in a portion P2 (P) on the side surface 20a2, a normal vector Vn2 is oriented toward a direction in between the X direction and the Z direction and, as illustrated in FIG. 1, is oriented toward a direction in between the X direction and the opposite direction of the Y direction. That is, the normal vector Vn2, in other words, the normal direction of the portion P2 is oriented toward a direction in between the X direction, the opposite direction of the Y direction, and the Z direction. Regarding the portion P2 (P), the X direction represents an example of the third direction, and the opposite direction of the Y direction represents an example of the second direction.

As illustrated in FIG. 1, the side surface 20a2 is configured in such a way that, when viewed from the opposite direction of the Z direction, the angular difference θ occurs between the orthogonal projection of the normal vector Vn2 at each position on the side surface 20a2 onto the virtual plane intersecting with the Z direction (i.e., the XY plane) and the X direction (i.e., the angular difference θ occurs between the arrow indicating Vn2 in FIG. 1 and the X direction).

As a result of forming the side surface 20a2 (20a) in such a way that the abovementioned state of the normal vector Vn2 is attained, it becomes possible to attain the state in which the normal direction of each portion P2 on the side surface 20a2 (20a), that is, the direction in which the normal vector Vn2 is oriented is inclined with respect to the direction of the crystal orientation [111].

As a result of the diligent research performed by the inventors, it became clear that the angular difference θ is desirably equal to 35°±5.5°.

In the configuration explained above, in the side surfaces 20a (20a1 and 20a2), the tangential direction at each position on the boundary line on the cross-sectional surface intersecting with the Z direction, that is, the tangential direction at each position on the dashed lines indicating the side surfaces 20a1 and 20a2 illustrated in FIG. 1 can be said to be extending in a direction in between the X direction and the Y direction or in between the X direction and the opposite direction of the Y direction.

As a result of the diligent research performed by the inventors, it became clear that an angular difference α, which represents an acute angle, between the tangential direction at each position on the boundary line and the X direction is desirably equal to 55°±5.5°. The angular difference α represents an example of a second angular difference.

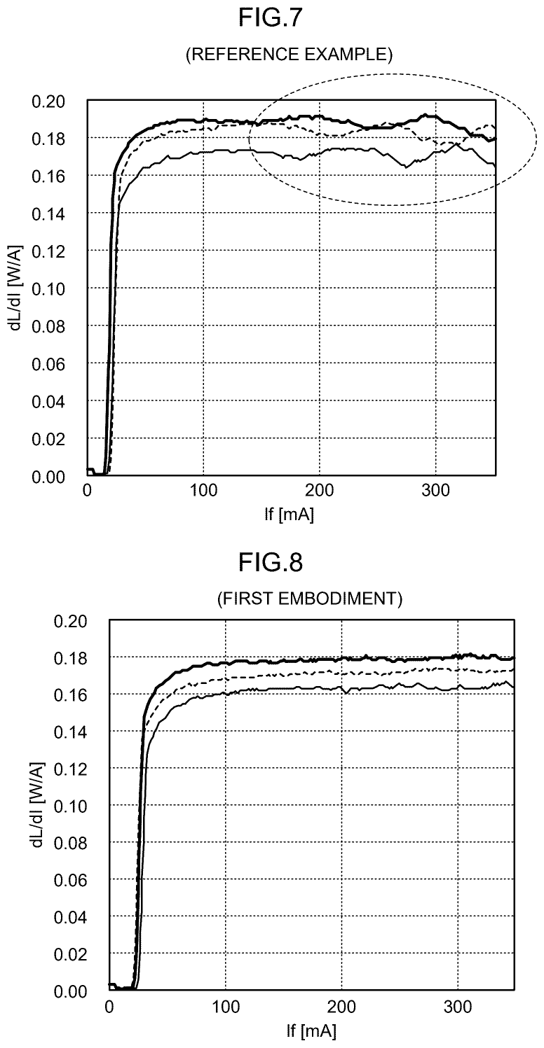

FIG. 7 is a graph that, in the case in which the buried optical waveguide structure 100R according to the reference example transmits the output light of a laser device, illustrates an example of the relationship between an applied current If [mA], which is applied to the laser device, and an increase rate dL/dI (W/A) of the light output of the laser device with respect to the applied current (hereinafter, the relationship is referred to as the current-increase rate characteristic). FIG. 8 is a graph that, in the case in which the buried optical waveguide structure 100A (100) according to the first embodiment transmits the output light of a laser device, that illustrates an example of the relationship between the applied current If [mA], which is applied to the laser device, and the increase rate dL/dI (W/A) of the light output of the laser device with respect to the applied current.

In the reference example illustrated in FIG. 7, due to the appearances of the voids 50a and 50b, there occurs a disturbance (kink) in the current-increase rate characteristic as illustrated by the portion enclosed using a dashed line in FIG. 7. In contrast, in the first embodiment as illustrated in FIG. 8, the generation of the voids 50a and 50b is held down, and there is no disturbance in the current-increase rate characteristic as seen in FIG. 7.

As explained above, according to the first embodiment, portions that have the normal direction oriented toward the direction of the crystal orientation [111] can be prevented from appearing on the side surfaces 20a. Hence, it becomes possible to hold down the generation of the voids 50a and 50b corresponding to the portions that have the normal direction oriented toward the direction of the crystal orientation [111]. In turn, it becomes possible to hold down a situation in which the reflection of the light from the voids 50a and 50b causes a decline in the transmission characteristics of the light in the waveguide 20.

The side surfaces 20a that enable achieving the abovementioned effects can be configured by setting the end edge 42a of the dielectric substance mask 42 in such a way that the tangential direction at each position on the end edge 42a extends in a direction in between the X direction and the Y direction or in between the X direction and the opposite direction of the Y direction. In that case, the angular difference α, which represents an acute angle, between the tangential direction at each position on the end edge 42a and the X direction is desirably equal to 55°±5.5°.

### Second Embodiment

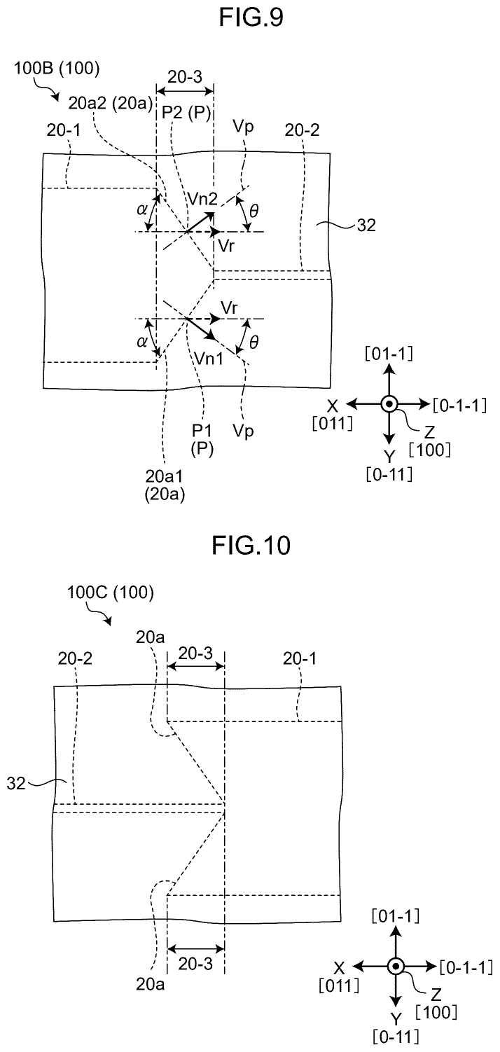

FIG. 9 is a planar view of a buried optical waveguide structure 100B (100) according to a second embodiment. When FIG. 9 is compared with FIG. 1 illustrating the configuration according to the first embodiment, it is clear that the positions of the waveguides 20-2 and 20-3 with respect to the waveguide 20-1 according to the second embodiment are reversed from the positions according to the first embodiment. In the second embodiment, the opposite direction of the X direction, that is, the direction of the crystal orientation [0-1-1] represents an example of a third direction.

In the buried optical waveguide structure 100B (100) according to the second embodiment, the normal direction at each position on the side surfaces 20a of the waveguide 20-3 is set to a direction inclined with respect to the direction of the crystal orientation [1-1-1]. The direction of the crystal orientation [1-1-1] represents the exactly intermediate direction between the opposite direction of the X direction and the Z direction.

In an identical manner to the first embodiment, in the portion P1 (P) on the side surface 20al, the normal vector Vn1 is oriented toward a direction in between the opposite direction of the X direction and the Z direction and, as illustrated in FIG. 9, is oriented toward a direction in between the opposite direction of the X direction and the Y direction. That is, the normal vector Vn1, in other words, the normal direction of the portion P1 is oriented toward a direction in between the X direction, the Y direction, and the Z direction.

As illustrated in FIG. 9, the side surface 20a1 is configured in such a way that, when viewed from the opposite direction of the Z direction, the angular difference θ occurs between the orthogonal projection of the normal vector Vn1 at each position on the side surface 20a1 onto the virtual plane intersecting with the Z direction (i.e., the XY plane) and the opposite direction of the X direction (i.e., the angular difference θ occurs between the arrow indicating Vn1 in FIG. 9 and the opposite direction of the X direction).

As a result of forming the side surface 20a1 (20a) in such a way that the abovementioned state of the normal vector Vn1 is attained, it becomes possible to attain the state in which the normal direction of each portion P1 on the side surface 20a1 (20a), that is, the direction in which the normal vector Vn1 is oriented is inclined with respect to the direction of the crystal orientation [1-1-1].

In an identical manner to the portion P1 illustrated in FIG. 9, in the portion P2 (P) on the side surface 20a2, the normal vector Vn2 is oriented toward a direction in between the opposite direction of the X direction and the Z direction and, as illustrated in FIG. 9, is oriented toward a direction in between the opposite direction of the X direction and the opposite direction of the Y direction. That is, the normal vector Vn2, in other words, the normal direction of the portion P2 is oriented toward a direction in between the opposite direction of the X direction, the opposite direction of the Y direction, and the Z direction.

As illustrated in FIG. 9, the side surface 20a2 is configured in such a way that, when viewed from the opposite direction of the Z direction, the angular difference θ occurs between the orthogonal projection of the normal vector Vn2 at each position on the side surface 20a2 onto the virtual plane intersecting with the Z direction (i.e., the XY plane) and the opposite direction of the X direction (i.e., the angular difference θ occurs between the arrow indicating Vn2 in FIG. 9 and the opposite direction of the X direction).

As a result of forming the side surface 20a2 (20a) in such a way that the abovementioned state of the normal vector Vn2 is attained, it becomes possible to attain the state in which the normal direction of each portion P2 on the side surface 20a2 (20a), that is, the direction in which the normal vector Vn2 is oriented is inclined with respect to the direction of the crystal orientation [1-1-1].

As a result of the diligent research performed by the inventors, it became clear that the angular difference θ is desirably equal to 35°±5.5° in an identical manner to the first embodiment.

In the configuration explained above, in the side surfaces 20a (20a1 and 20a2), the tangential direction at each position on the boundary line on the cross-sectional surface intersecting with the Z direction, that is, the tangential direction at each position on the dashed lines indicating the side surfaces 20a1 and 20a2 illustrated in FIG. 9 can be said to be extending in a direction in between the opposite direction of the X direction and the Y direction or in between the opposite direction of the X direction and the opposite direction of the Y direction.

As a result of the diligent research performed by the inventors, it became clear that the angular difference α, which represents an acute angle, between the tangential direction at each position on the boundary line and the X direction is desirably equal to 55°±5.5° in an identical manner to the first embodiment.

Thus, according to the second embodiment too, it becomes possible to achieve identical effects to the effects achieved in the first embodiment.

### Third Embodiment

FIG. 10 is a planar view of a buried optical waveguide structure 100C according to a third embodiment. When FIG. 10 is compared with FIG. 1 illustrating the configuration according to the first embodiment, it is clear that the positions of the two side surfaces 20a are reversed from the positions according to the first embodiment. However, the shape of each side surface 20a is identical to the shape of either one of the side surfaces 20a according to the first embodiment. Hence, according to the third embodiment too, it becomes possible to achieve identical effects to the effects achieved according to the first embodiment.

Fourth embodiment, fifth embodiment, and sixth embodiment

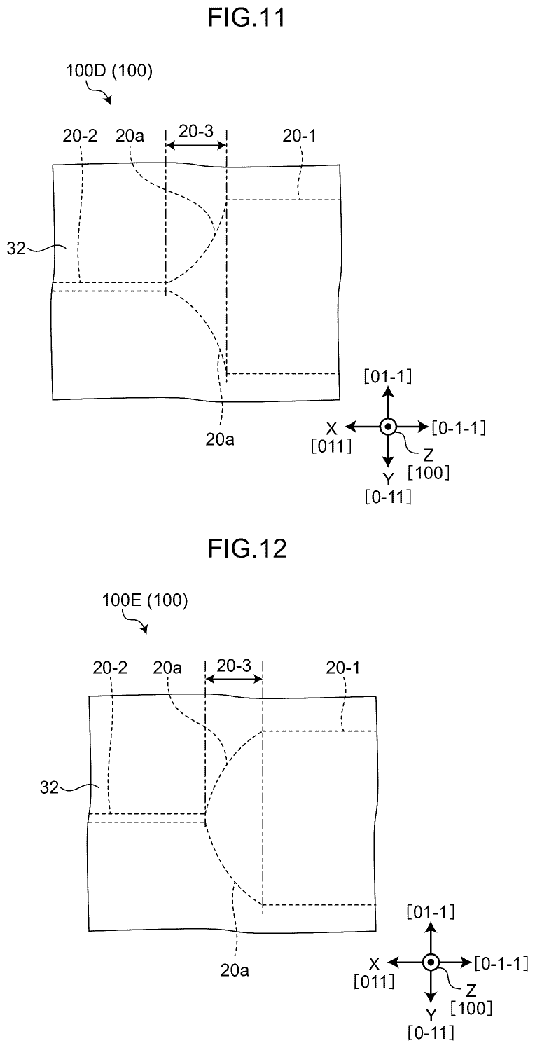

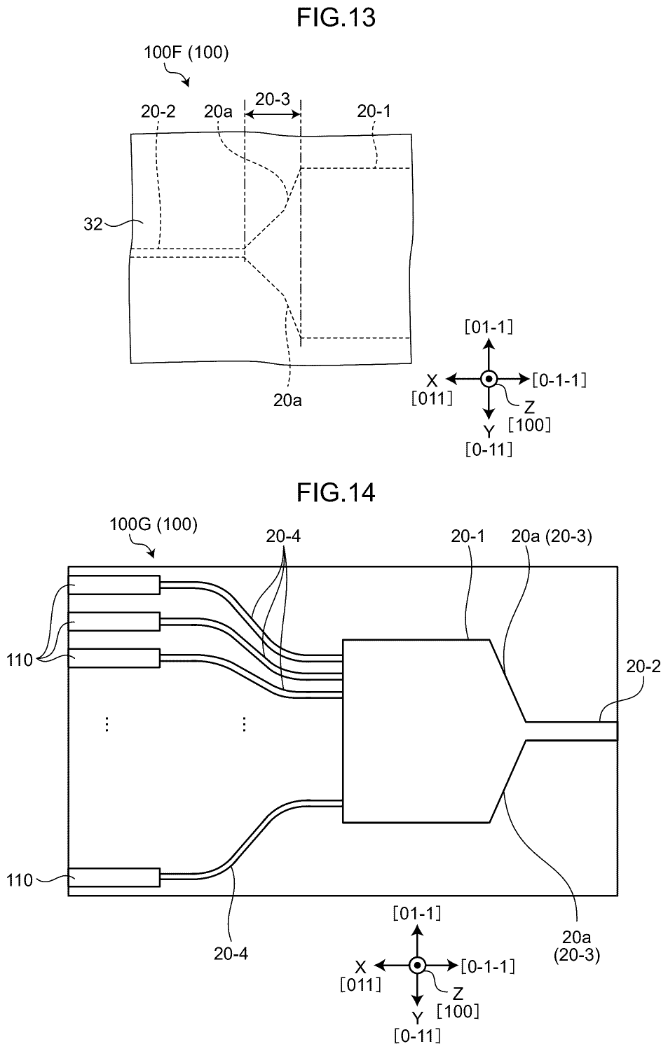

FIG. 11 is a planar view of a buried optical waveguide structure 100D (100) according to a fourth embodiment. FIG. 12 is a planar view of a buried optical waveguide structure 100E (100) according to a fifth embodiment. FIG. 13 is a planar view of a buried optical waveguide structure 100F (100) according to a sixth embodiment.

In the first to third embodiments, the side surfaces 20a are formed in a substantially planar shape. In contrast, as illustrated in FIGS. 11 to 13, in the fourth to sixth embodiments, each side surface 20a has the shape of a curved surface or has the shape including a plurality of bent planes, and includes a depressed portion or a projected portion. In the fourth embodiment, the side surfaces 20a are formed in the shape of a concave curved surface. In the fifth embodiment, the side surfaces 20a are formed in the shape of a convex curved surface. In the sixth embodiment, on each side surface 20a, a groove is formed in which two planes extending in different directions intersect with each other. Alternatively, on each side surface 20a, a ridge line can be formed in which two planes extending in different directions intersect with each other.

As explained in the fourth to sixth embodiments, even when the side surfaces 20a include a depressed portion or a projected portion, as long as the normal direction at each position on each side surface 20a is oriented in a direction inclined with respect to the direction of the crystal orientation [111] or the direction of the crystal orientation [1-1-1], it becomes possible to achieve identical effects to the effects achieved according to the first embodiment. Meanwhile, the shapes of the side surfaces 20a are not limited to the shapes according to the embodiments described below.

### Seventh Embodiment

FIG. 14 is a planar view of a buried optical waveguide structure 100G (100) according to a seventh embodiment. The buried optical waveguide structure 100G (100) is configured as an integrated semiconductor laser device. The buried optical waveguide structure 100G includes: a plurality of waveguides 20-4 that is optically connected to the waveguide 20-1 on a side that is different from a side on which the waveguide 20-1 is connected to the waveguide 20-2; and semiconductor lasers 110 that are optically connected to the waveguides 20-4 on a side that is different from a side on which the waveguides 20-4 is connected to the waveguide 20-1. The semiconductor lasers 110 are, for example, laser devices such as DFB lasers. The waveguide 20-2 can be configured as a semiconductor optical amplifier. Regarding the waveguide 20-1, apart from using the structures explained in the embodiments described above, it is also possible to use appropriately-modified configurations or to use a combination of configurations. The buried optical waveguide structure 100G according to the seventh embodiment can be applied in an identical configuration to the configuration disclosed in Japanese Patent No. 5100881.

While certain embodiments and modification examples have been described, these embodiments and modification examples have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Moreover, regarding the constituent elements, the specifications about the configurations and the shapes (structure, type, direction, shape, size, length, width, thickness, height, number, arrangement, position, material, etc.) can be suitably modified.

For example, on the end surface, the normal directions at all positions need not be inclined with respect to the direction of the crystal orientation [111] or the direction of the crystal orientation [1-1-1].

According to the disclosure, it becomes possible to provide a buried optical waveguide structure, an integrated semiconductor laser device, and a buried optical waveguide structure manufacturing method in a new and improved manner.

Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A buried optical waveguide structure comprising:
a waveguide including a first cladding layer, a core layer, and a second cladding layer that are layered in a first direction; and
a burying layer that is adjacent to the waveguide in a direction intersecting with the first layer,
the buried optical waveguide structure being made of semiconductor crystals, wherein
the waveguide includes
a first portion that has a first width in a second direction intersecting with the first direction and that extends in a third direction intersecting with both of the first direction and the second direction,
a second portion that is shifted from the first portion in the third direction, that is optically connected to the first portion, that has a second width which is smaller than the first width in the second direction, and that extends in the third direction, and
a third portion that is adjacent to the first portion in the third direction, that is optically connected to the first portion, and that has an end surface in the third direction,
the first direction represents a direction of crystal orientation [100],
the second direction represents either a direction of crystal orientation [0-11] or a direction of crystal orientation [01-1],
the third direction represents either a direction of crystal orientation [011] or a direction of crystal orientation [0-1-1], and
a normal direction at each position on the end surface is oriented toward a direction either in between the first direction, the second direction, and the third direction or in between the first direction, an opposite direction of the second direction, and the third direction, and is inclined with respect to either a direction of crystal orientation [111] or a direction of crystal orientation [1-1-1].

2. The buried optical waveguide structure according to claim 1, wherein, when viewed from an opposite direction of the first direction, a first angular difference has between an orthogonal projection of a vector and the third direction, the vector being along a normal direction at each position on the end surface, the orthogonal projection being an orthogonal projection of the vector onto a virtual plane intersecting with the first direction.

3. The embedded optical waveguide structure according to claim 2, wherein the first angular difference is an acute angle having an absolute value of 35°±5.5°.

4. The buried optical waveguide structure according to claim 1, wherein the end surface includes a portion extending in the third direction along the second direction.

5. The buried optical waveguide structure according to claim 1, wherein the end surface includes a portion extending in an opposite direction of the third direction along the second direction.

6. The buried optical waveguide structure according to claim 1, wherein the end surface includes either a projected portion or a depressed portion.

7. The buried optical waveguide structure according to claim 1, wherein, in the end surface, a tangential direction at each position on a boundary line on a cross-sectional surface intersecting with the first direction extends along a direction either in between the third direction and the second direction or in between the third direction and an opposite direction of the second direction.

8. The buried optical waveguide structure according to claim 7, wherein a second angular difference is an acute angle between the tangential direction and the third direction and has an absolute value of 55°±5.5°.

9. The buried optical waveguide structure according to claim 1, wherein the first portion and the third portion form multimode interference waveguide that are optically connected with the second portion.

10. The buried optical waveguide structure according to claim 1, wherein the waveguide and the burying layer are made of a III-V compound semiconductor having a zinc blende structure.

11. A buried optical waveguide structure comprising:
a waveguide including a first cladding layer, a core layer, and a second cladding layer that are layered in a first direction; and
a burying layer that is adjacent to the waveguide in a direction intersecting with the first layer,
the buried optical waveguide structure being made of semiconductor crystals, wherein
the waveguide includes
a first portion that has a first width in a second direction intersecting with the first direction and that extends in a third direction intersecting with both of the first direction and the second direction,
a second portion that is shifted from the first portion in the third direction, that is optically connected to the first portion, and that has a second width which is smaller than the first width in the second direction, and that extends in the third direction, and
a third portion that is adjacent to the first portion in the third direction, that is optically connected to the first portion, and that has an end surface in the third direction,
the first direction represents direction of crystal orientation [100],
the second direction represents direction of crystal orientation [0-11] or direction of crystal orientation [01-1],
the third direction represents direction of crystal orientation [011] or direction of crystal orientation [0-1-1], and
the end surface includes a portion that has a normal direction
oriented toward a direction either in between the first direction, the second direction, and the third direction or in between the first direction, an opposite direction of the second direction, and the third direction, and
inclined with respect to either a direction of crystal orientation [111] or a direction of crystal orientation [1-1-1].

12. The buried optical waveguide structure according to claim 11, wherein, in the end surface, a boundary line on a cross-sectional surface intersecting with the first direction includes a portion having a tangential direction extending along a direction in between the second direction and the third direction.

13. An integrated semiconductor laser device comprising:
the buried optical waveguide structure according to claim 1;
a plurality of waveguides that is optically connected to the first portion on a side that is different from a side on which the first portion is connected to the second portion; and
semiconductor lasers that are optically connected to the waveguides on a side that is different from a side on which the waveguides are connected to the first portion.

14. An integrated semiconductor laser device comprising:
the buried optical waveguide structure according to claim 11;
a plurality of waveguides that is optically connected to the first portion on a side that is different from a side on which the first portion is connected to the second portion; and
semiconductor lasers that are optically connected to the waveguides on a side that is different from a side on which the waveguides are connected to the first portion.

15. A buried optical waveguide structure manufacturing method comprising:
layering, in a first direction, a first cladding layer, a core layer, and a second cladding layer on a substrate intersecting with the first direction to form a layered body;
performing etching on the layered body in an opposite direction of the first direction to form a depressed portion and a waveguide adjacent to the depressed portion; and
burying the depressed portion with a burying layer, wherein
the waveguide includes
a first portion that has a first width in a second direction intersecting with the first direction and that extends in a third direction intersecting with both of the first direction and the second direction,
a second portion that is shifted from the first portion in the third direction, that is optically connected to the first portion, that has a second width which is smaller than the first width in the second direction, and that extends in the third direction, and
a third portion that is adjacent to the first portion in the third direction, that is optically connected to the first portion, and that has an end surface in the third direction,
the first direction represents a direction of crystal orientation [100],
the second direction represents either a direction of crystal orientation [0-11] or a direction of crystal orientation [01-1],
the third direction represents either a direction of crystal orientation [011] or a direction of crystal orientation [0-1-1], and
the end surface includes a portion that has a normal direction
oriented toward a direction either in between the first direction, the second direction, and the third direction or in between the first direction, an opposite direction of the second direction, and the third direction, and
inclined with respect to either a direction of crystal orientation [111] or a direction of crystal orientation [1-1-1].
